(19) United States
(12) Patent Application Publication
(10) Pub. No.: US 2017/0086312 A1
(43) Pub. Date: Mar. 23, 2017

(54) PROCESS FOR PROTECTING AN ELECTRONIC DEVICE BY SELECTIVE DEPOSITION OF POLYMER COATINGS

(71) Applicants: Syed Taymur Ahmad, Chicago, IL (US); Bruce Acton, Bettendorf, IA (US)

(72) Inventors: Syed Taymur Ahmad, Chicago, IL (US); Bruce Acton, Bettendorf, IA (US)

(21) Appl. No.: 15/268,373

(22) Filed: Sep. 16, 2016

Related U.S. Application Data
(60) Provisional application No. 62/220,230, filed on Sep. 17, 2015.

(51) Int. Cl. H05K 5/00; G06F 1/16; H04B 1/3888; H05K 3/28

(52) U.S. Cl. CPC H05K 5/0069; H05K 3/28; H05K 5/0017; G06F 1/1626; G06F 1/1616; H04B 1/3888

(57) ABSTRACT

Methods for protecting an electronic device from contaminants by applying different polymeric materials to different vital components of a device are disclosed. In one embodiment, the method comprises applying an electrically insulating polymer, such as an acrylic-based polymer, to one or more connectors and components located on the printed circuit board of the device. The method further comprises applying a polymer capable of carrying a charge, such as a silicone-based polymer, to different connectors and components on the printed circuit board. The method leads to different components being coated with a different polymers. Electronic devices that are protected by such polymeric, hydrophobic coatings are also disclosed, such as smart phones, computers, and gaming devices.

This application claims priority to U.S. Provisional Application No. 62/220,230, filed on Sep. 17, 2015, which is incorporated herein by reference in its entirety.

The present disclosure generally relates to methods of protecting electronic devices, such as a cell phone or computer, by applying an electrically insulating polymer to certain device components, and a polymer capable of conducting a charge to different device components. The present disclosure also relates to methods of rendering an electronic device hydrophobic by applying these different materials to different components on the printed circuit board of the device. The present disclosure further relates to devices protected by such polymeric coatings, including any device containing a printed circuit board.

### BACKGROUND

Electronic devices are comprised of electrically conductive and insulating components, which can be adversely affected by a variety of contaminants. Exposure to liquids like water, will often lead to corrosion of these components that will eventually destroy the function of the electronic device. In addition, as such devices become more sophisticated with increased functionality, they are being used in more hazardous environments that require greater protection from contaminants, especially liquids.

As a result, water resistant coatings are becoming a more popular form of protection of such devices. However, most water resistance technologies provide only one form of nano-coating (one molecule) and one method of application. Accordingly, there is need for coated electronic devices and methods that allow for protection of electronic devices from contaminates, such as liquids comprising water, including bodily fluids, such as sweat.

### SUMMARY

In view of the foregoing, there is disclosed a method for protecting an electronic device by applying different polymeric materials on specified components of the device. In one embodiment, the disclosed method generally comprises treating, in any order, the backside and front side of the printed circuit board. In one embodiment, treating the backside of the circuit board comprises: applying an electrically insulating polymer to the surface of at least one component located on the backside of the circuit board. Non-limiting examples of the components that can be treated with the insulating polymer include at least one component and/or connector chosen from a printed circuit board, such as a flexible printed circuit connector, an LCD, a battery connector, a speaker connector, a camera connector, a light connector, and combinations thereof.

The method next comprises curing the insulating polymer, followed by applying a polymer capable of conducting a charge to at least one different component than the component containing the insulating polymer. Non-limiting examples of the components on which the polymer capable of conducting a charge is applied include at least one component and/or connector chosen from a power switch, a volume switch, RAM Chips, ROM Chips, USB charging port, MEMS, Microphone, SIM card housings, headphone jack, and combinations thereof.

The method of treating the front side of the printed circuit board comprises: applying an insulating polymer to the surface of at least component located on the front side of the circuit board. The previously mentioned components that are covered with the insulating polymer on the back side of the PCB are the same as on the front side, e.g., at least one component and/or connector chosen from an FPC connector, an LCD, a battery connector, a speaker connector, a camera connector, a light connector, and combinations thereof.

The method also comprises curing the insulating polymer, and applying a polymer capable of conducting a charge to at least one different component than the component containing the insulating polymer. The previously mentioned components that are covered with the polymer capable of conducting a charge on the back side of the PCB are the same as on the front side, e.g., at least one component and/or connector chosen from a power switch, a volume switch, RAM Chips, ROM Chips, USB charging port, MEMS, Microphone, SIM card housings, headphone jack, and combinations thereof.

The above methods next comprise assembling the electronic device by installing the printed circuit board and battery in a housing; connecting the male connectors of the device to base female connectors mounted on the back side of the printed circuit board; and applying the insulating polymer to the side of the connector in an amount sufficient to achieve wicking coverage around perimeter.

In one embodiment, the insulating polymer described herein has a hardness greater than the polymer capable of conducting a charge. The insulating polymer may comprise an acrylic-based polymer. Such a polymer can be fully cured when exposed to ambient conditions for 24 hours. In one embodiment, the polymer capable of conducting a charge comprises a silicone-based polymer. Such a polymer can be cured when exposed to ambient conditions for up to 30 minutes.

There is also disclosed an electronic device protected from contaminants by the treatment method described herein. For example, there is described a printed circuit board having a front side and a back side, the backside comprising: at least one female connector having an insulating polymer located around the perimeter; at least one internal component having the insulating polymer located thereon; and at least one different internal component having a polymer capable of conducting a charge located thereon.

In an embodiment, the electronic device, such as a smart phone, described herein comprises: a printed circuit board having a front side and a back side, the backside comprising:
at least one internal connector having an electrically insulating polymer located around the perimeter; at least one internal component having the insulating polymer located thereon; and at least one different internal component having a polymer capable of conducting a charge located thereon. In this embodiment, the front side of the printed circuit board comprises: at least one internal connector having the insulating polymer located around the perimeter; at least one camera having the insulating polymer located around the perimeter; at least one internal component having the insulating polymer located thereon; and at least one different internal component having a polymer capable of conducting a charge located thereon.

It is to be understood that both the foregoing general description and the following detailed description are exemplary and explanatory only and are not restrictive of the invention, as claimed.

### BRIEF DESCRIPTION OF THE DRAWINGS

The accompanying figures, which are incorporated in and constitute a part of this specification, illustrate several embodiments of the invention and together with the description, serve to explain the principles of the invention.

FIG. 1 is a flow chart showing the general method used to treat a printed circuit board according to an embodiment.

FIG. 2 is a flow chart showing a more specific method used to treat a printed circuit board with an acrylic-based polymer and a silicone based polymer according to an embodiment.

FIG. 3 is a flow chart showing a method used to treat a printed circuit board in a production process according to an embodiment.

FIG. 4 is a flow chart showing a method used to treat a printed circuit board on a disassembled cell phone according to an embodiment.

FIG. 5 is a photograph showing the back side of a printed circuit board showing where the insulating polymer and the polymer capable of carrying a charge are deposited.

FIG. 6 is a photograph showing the front side of a printed circuit board showing where the insulating polymer and the polymer capable of carrying a charge are deposited.

FIG. 7 is a photograph showing the back side of the printed circuit board of FIG. 5, with additional description of where the insulating polymer and the polymer capable of carrying a charge are deposited.

FIG. 8 is a photograph showing the back side of the printed circuit board of FIG. 6, with additional description of where the insulating polymer and the polymer capable of carrying a charge are deposited.

### DETAILED DESCRIPTION

As used herein, “ambient conditions” refers to 72° F. and 45% humidity.

As used herein, “inert to conductivity” means that the material does not conduct or resist electrical charge.

As used herein, “insulating polymer” means the polymer does not conduct electricity.

In one embodiment, the “water contact angle” is measured using droplets of water that are placed onto a 304 stainless steel surface that has been treated with any of the described polymer(s). For example, a first polymer having a water contact angle greater than 90 degrees after curing means that a 304 stainless steel surface has been coated with the first polymer, which is then cured prior to a droplet of water being dropped thereon. The same is true for the water contact angle for a second polymer.

Other contact angles may also be used to characterize the hydrophobic properties of the described coatings placed on different substrates. For example, oil contact angles are described herein that were measured on treated glass slides and treated aluminum substrates. The methods used to measure these contact angles are similar to those described for the treated 304 stainless steel surface.

To protect an electronic device from contaminants, such as water and bodily fluid, there is disclosed a method of different polymers to different connections and components located on the printed circuit board.

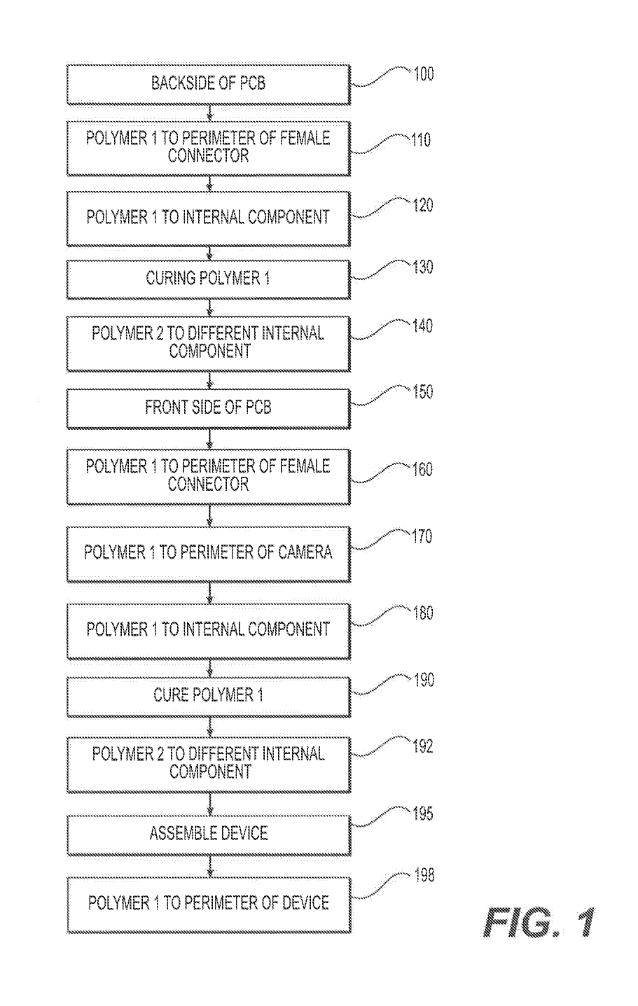

Referring now to the FIG. 1 which depicts a flow chart of an embodiment of the present disclosure, specifically the general method of protecting an electronic device that comprises a printed circuit board 100.

As described in FIG. 1, the method comprises applying a first polymer to one or more female connectors 110 and components 120 located on the backside of a printed circuit board 100. The method then comprises curing the first polymer 130, before applying a second polymer to a different set of one or more components 140 on the backside of the PCB. Both the first polymer and the second polymer exhibit hydrophobic properties, as determined by a water contact angle greater than 90° such at least 110°, such as 115° or greater, or any contact angle ranging from 100° to 120°.

Treating the front side of the circuit board 150 comprises applying the first polymer around the perimeter of at least one female connector 160, around the perimeter of one or more connected cameras 170, to the surface of at least one internal component 180, or combinations thereof. Next, the first polymer is cured 190, prior to applying the second polymer to a different set of one or more internal components 192.

As further described in the flow chart of FIG. 1, the method next comprises assembling the electronic device 195. Assembling the electronic device includes installing the printed circuit board and a battery in an appropriate housing and connecting the male connectors of the device to base female connectors mounted on the back side of the printed circuit board. Finally, the first polymer is applied to the side of the housing, such as in an amount sufficient to achieve wicking coverage around perimeter 198.

In one embodiment, the first polymer in electrically insulating and has a higher hardness than the second polymer. For example, the first polymer may comprise an acrylic-based polymer, such as a fluoroacrylate. One non-limiting example of a fluorinated acrylic that can be used herein is shown in (I) below:

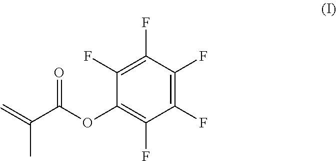 [SMILES: C=C(C)C(=O)Oc1c(F)c(F)c(F)c(F)c1F]

Upon curing, a coating comprising the acrylic-based polymer provides a hard barrier that exhibits excellent electrically insulating and anti-corrosion properties. Curing of the fluorinated, acrylic-based polymer typically comprises exposing the polymer to ambient conditions for at least 24 hours. This may be done under thermal conditions, for times less than 24 hours. Curing is done at a temperature and for a time sufficient to cure the polymer material. In one embodiment, first polymer is applied to the connector(s) and/or components in a single layer. In one embodiment, the thickness of each acrylic-based polymer layer ranges from 20 to 1000 nm.

In one embodiment, the second polymer is capable of carrying a charge, such as a silicone-based polymer. One non-limiting example of a silicone-based polymer that can be used herein is aliphatic siloxane, as shown in (II) below:

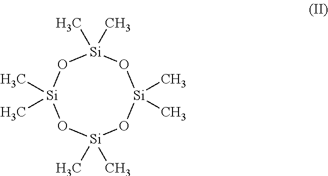

Upon curing, a coating comprising the silicon-based polymer provides improved surface properties, including improved hydrophobicity, improved oleophobicity and reduced friction. The coated surface also exhibits anti corrosion properties. Curing of the silicone-based polymer typically comprises exposing the polymer to ambient conditions for at least 30 minutes. Alternatively, curing may be done under thermal conditions, such as heating above 80° C., such as from 90-110° C. for a time sufficient to cure the polymer. Such times range are typically up to 5 minutes, but may range from 2 to 10 minutes depending on the polymer composition and layer thickness. In one embodiment, the thickness of the silicone-based polymer layer ranges from 50 to 500 nm.

The silicone-based polymer may further comprises at least one hydrophobic agent, such as an organometallic compound. In one embodiment, the organometallic halogen material comprises at least one alkyl group and at least one halogen atom linked to a metal atom. Non-limiting examples of the metal atom include titanium, zirconium, tantalum, germanium, boron, strontium, iron, praseodymium, erbium, cerium, lithium, magnesium, aluminum, phosphorus and silicon.

In one embodiment, the first and second polymers are applied by at least one automated or manual deposition technique independently chosen from dipping, spraying, vacuum deposition, syringe dispensing, and wipe coating. One particularly useful automated coating system that can be used to deposit the first and/or second polymer is The Nordson ASYMTEK™ Select Coat® SL-940 Series conformal coating system. The Delta 6 SELECTIVE COATING/DISPENSING SYSTEM sold by Precision Valve & Automation, Inc. (PVA), is another robotic conformal coating/dispensing system that can be used to deposit such polymers. For syringe dispensing, the ST100S,™ also sold by PVA, can be used.

Additional steps may be carried out before or after applying the first and/or second polymers. For example, in one embodiment, the method may further comprise cleaning the electronic component prior to applying either polymer material to remove dust, grime or other surface dirt.

Non-limiting examples of the electronic component that may be coated using the disclosed method include a power switch, a volume switch, a light, a liquid crystal display, a touch-screen, a touch panel, a camera, an antenna, an internal connector, such as a printed circuit board, and combinations thereof.

It is understood that when an internal connector has a male end and a female end, the method comprises applying the polymers to both the male end and the female end of the internal connector prior to connecting the male end to the female end.

There is also disclosed an electronic device that is protected from contaminants, such as water, because it comprises a hydrophobic polymer on at least one internal connector and/or one internal component.

Non-limiting examples of at least one or more devices that can be protected using the disclosed method include a cellular phone, a personal digital assistant (PDA), a tablet, a notebook, a laptop, a desktop computer, a music player, a camera, a video recorder, a battery, an electronic reader, a radio device, a gaming device, a server, headphones, terminal blocks, and control panels. In addition, other devices that can be protected using the disclosed method include a wearable device, a medical device, a radio controlled device, an industrial device, and an appliance device.

As discussed, both the first polymer and the second polymer exhibit hydrophobic properties, as determined by a water contact angle greater than 90° such that the first layer and second layer form a multilayer, hydrophobic coating on top of the internal component. In one embodiment, the first and second polymers have a water contact angle of at least 110°, such as 115° or greater, or any contact angle ranging from 90° to 120°, such as 100° to 120°.

It has been discovered that electronic devices that have been protected as described herein, have increased water resistance by at least one order of magnitude, as measured by the time to malfunction when immersed in water. In particular, the Inventors have discovered that by providing the multilayer, hydrophobic coating as a barrier layer on the vital, and highly susceptible parts of an electronic device, water resistance of the device can increase at least 10 times, such as more than 25 times, or even more than 50 times when compared to an unprotected device. Furthermore, because the multilayer, hydrophobic coating described herein is inert to conductivity, it does not interfere with the function of the resulting electronic device, while adding the improved water resistance.

Low surface tension of the coating solution as disclosed herein provides increased surface wetting, especially under low profile components. The polymers described herein also provides excellent repellency, anti-wetting and anti-sticking properties against fluids, including but not limited to water, hydrocarbons, silicones and photoresists. As a result, the dried film has low surface energy allowing water-based liquids to bead and drain freely.

In addition the polymers described herein, when applied as coatings, are insoluble in solvents such heptane, toluene and water. An additional benefit associated with the polymers described herein in their flexibility. As these layers do not require thermal treatment, or harsh chemicals, they can be applied to many different substrates, including glass, metals, such as aluminum, stainless, and polymers.

The features and advantages of the present invention are more fully shown by the following examples which are provided for purposes of illustration, and are not to be construed as limiting the invention in any way.

### EXAMPLE

### Example 1

The following examples provide a step-by-step process of protecting a smart phone from contaminants by applying two different polymers to different components of the smart phone prior to final assembly of the device.

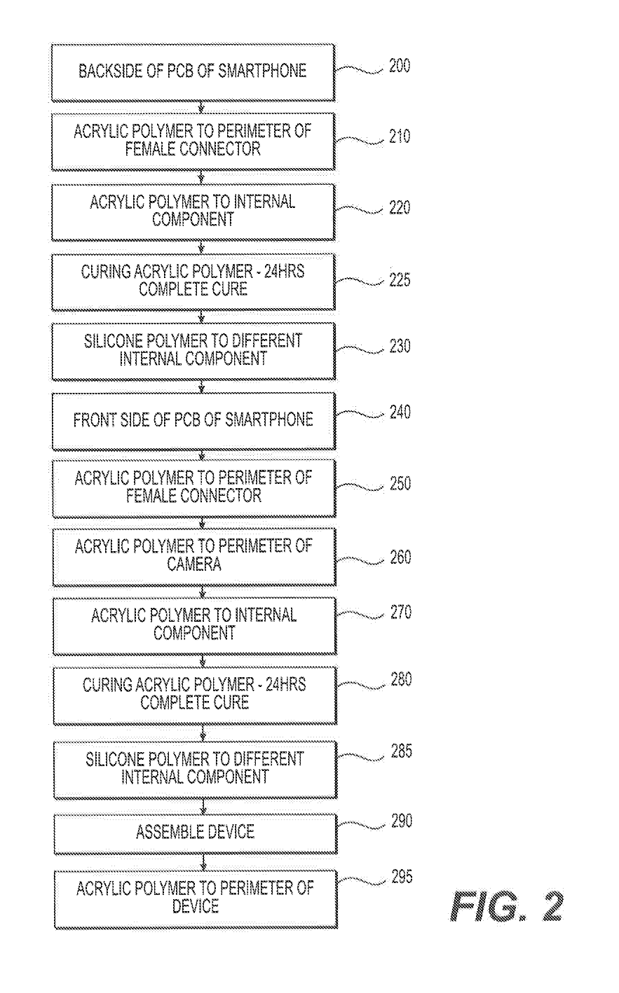

The process is described in FIG. 2, which is referred to herein, and applied to a disassembled smart phone. The backside of a printed circuit board (PCB) 200 was first treated. A fluorinated acrylic polymer was applied around the perimeter of a flexible printed circuit (FPC) based female connector of the back side of the PCB 210. This same polymer was then applied to various internal components 220 located on the backside of the PCB 200.

Then the fluorinated acrylic polymer was cured by exposing it to ambient conditions for 24 hours 225. After it was completely cured, an aliphatic siloxane was applied on various internal components 230 located on the backside of the PCB 200.

Next, the front side of the circuit board 240 was treated. This method comprised applying the fluorinated acrylic polymer around the perimeter of a flexible printed circuit (FPC) based female connector of the front side of the PCB 250. In subsequent steps, the fluorinated acrylic was then applied around the perimeter of a connected camera 260 and various internal components 270 located on the front side of the circuit board 240.

The fluorinated acrylic polymer was cured by exposing it to ambient conditions for 24 hours 280. After it was completely cured, the aliphatic siloxane was applied on various internal components 285 located on the front side of the PCB 240.

The method next comprised assembling the electronic device 290. Assembling the electronic device included installing the printed circuit board and a battery in appropriate housing and connecting male connectors of the device to the base female connectors mounted on the back side of the printed circuit board. Finally, the fluorinated acrylic polymer was applied the side of each connector until full wicking around the perimeter occurred 295.

The smart phone protected by the process of this Example was then tested to determine the efficacy of the inventive process. It was discovered that a smart-phone device protected with the different polymers as described above exhibited at least one order of magnitude longer protection time when compared to the same device not protected with the disclosed polymers.

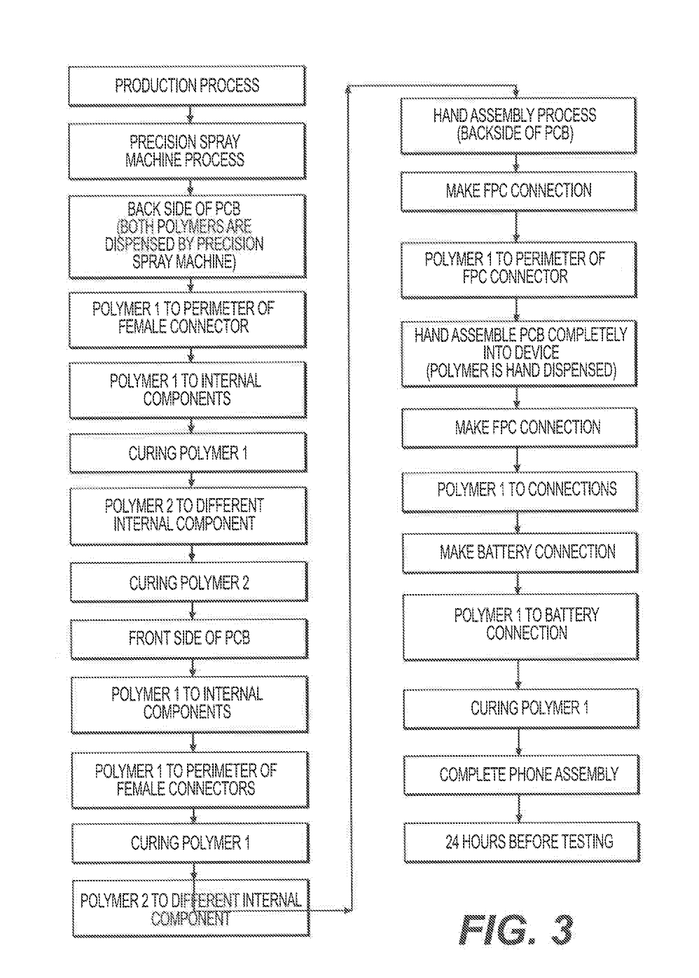

With reference to FIG. 3, there is described a production process according to the present disclosure that starts with a Precision Spray Machine Process that allows both polymers to be dispensed unto the backside of a PCB.

In one embodiment, Polymer 1 is applied to perimeter of female connector and to other Internal components, followed by curing the polymer. Next, Polymer 2 is applied to different internal components, which is followed by curing of Polymer 2.

With regard to the treatment of the front side of the PCB, again, Polymer 1 is applied to internal components of the PCB via the Precision Spray Machine. For example, Polymer 1 is applied to the perimeter of female connectors, which is followed by curing Polymer 1. Next, Polymer 2 is applied to different internal components, which is followed by curing of Polymer 2.

FIG. 3 further shows the Hand Assembly Process that is applied to the backside of the PCB. There is shown a connection being made with the FPC connection. Polymer 1 is applied to the perimeter of FPC Connector. Next, hand assembly is used to incorporate the PCB completely into the device, with the polymer being hand dispensed. This figure shows various connections being made including the FPC connections, and battery connection, with Polymer 1 being added to the connections, followed by the curing of Polymer 1. After the phone assembly is complete, it is set aside for 24 Hours before testing.

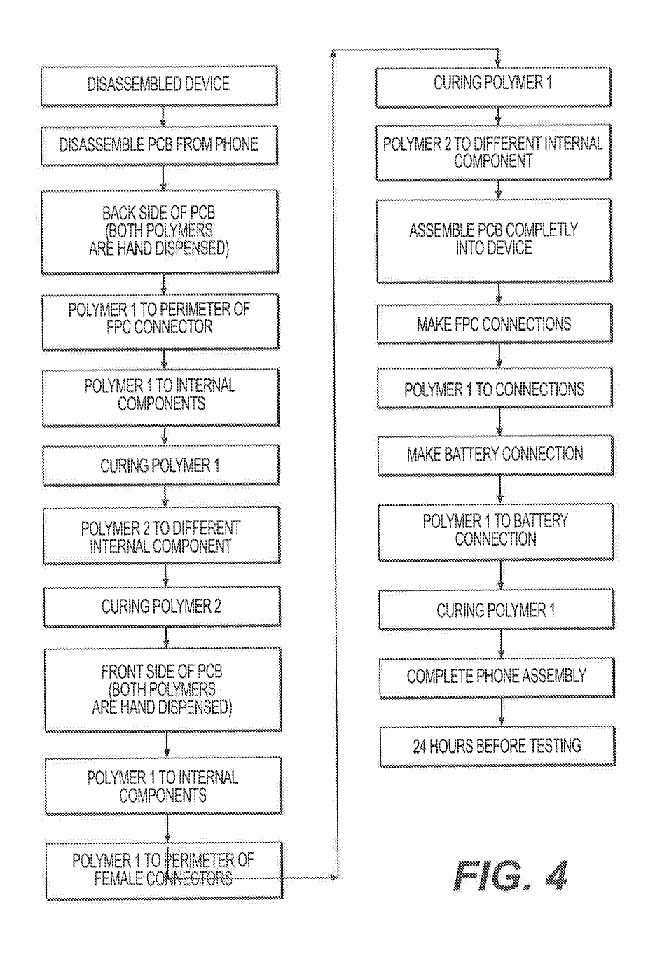

With reference to FIG. 4, there is described a process according to the present disclosure that starts with a dissembled device, generally with disassembling the PCB from a smart phone. To the back side of the PCB, both polymers are hand dispensed. For example, Polymer 1 is dispensed to the perimeter of FPC Connector, and other internal components, which is followed by curing Polymer 1. Next, Polymer 2 is applied to different internal component, which is followed by curing Polymer 2.

With regard to the front side of the PCB, again both Polymers are hand dispensed, with Polymer 1 being applied to internal components, including to the perimeter of female connectors. Polymer 1 is then cured. Polymer 2 is then applied to different internal component.

The process next focuses on the assembly of the device, which includes assembling the PCB completely into the device in order to make various connections, including FPC connections followed by applying Polymer 1 to the connections. Next, a battery connection is made, followed by applying Polymer 1 to the connection and curing Polymer 1. After the phone assembly is complete, it is set aside for 24 Hours before testing.

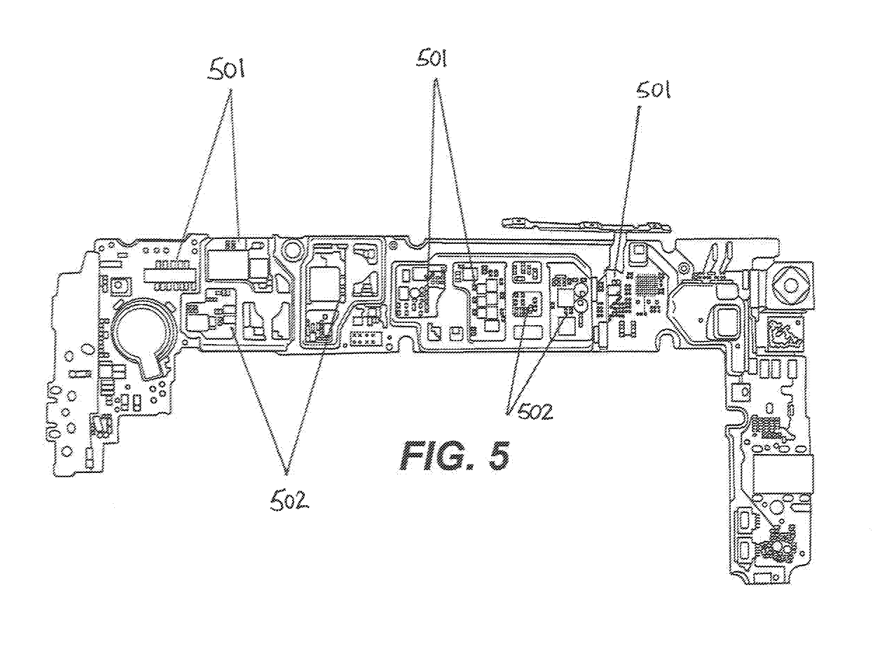

In an embodiment according to the present disclosure, and with reference to FIG. 5, there is shown the component locations for the different insulating 501 and conducting 502 coatings on the backside of a PCB according to the present disclosure. It is shown in this figure the coatings specific to the power and volume switches, as well as LCD and FPC connector areas. Other areas described in this figure include battery connection, backlight areas, and speaker connections. The locations of the insulating and conducting layers shown in FIG. 5 is representative purposes only, and is not limiting.

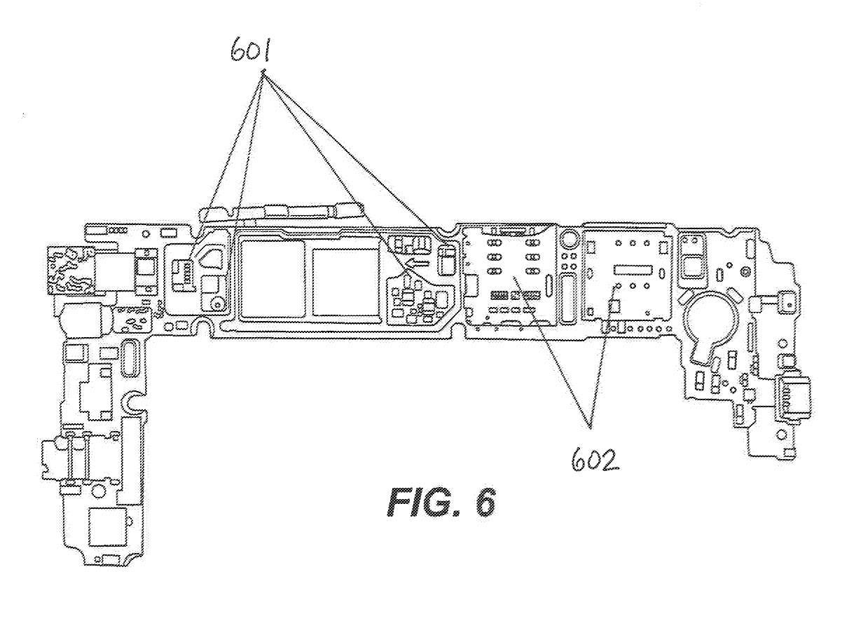

With reference to FIG. 6, which is the front side PCB shown in FIG. 5, there is shown the component locations for the different insulating 601 and conducting 602 coatings according to the present disclosure. It is shown in this figure the coatings specific to the camera, FPC connectors, as well as Dual SIM card housings, USB charging port, RAM, ROM Chips MEMS, Microphone, and the headphone jack. The locations of the insulating and conducting layers shown in FIG. 6 is representative purposes only, and is not limiting.

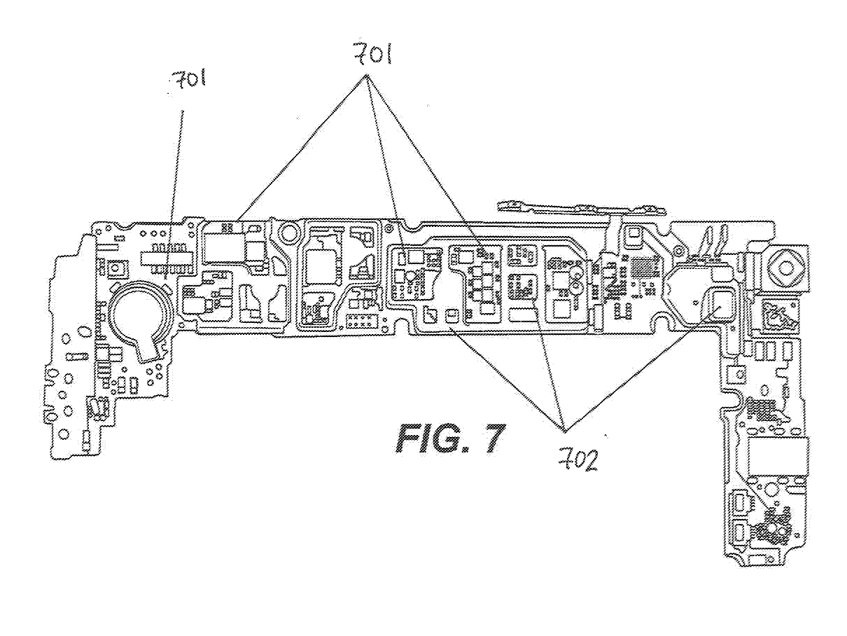

In an embodiment according to the present disclosure, and with reference to FIG. 7, there is shown the component locations for the different insulating 701 and conducting 702 coatings on the backside of a PCB according to the present disclosure. It is shown in this figure the coatings specific to the insulating coating around FPC connector area (for LCD), as well as for insulating coating on/around ZIF Flip-Lock connector for flexible pcb button power, volume switches. It is also shown in this figure, insulating coatings around the FPC battery clip, as well as insulating coatings around the power supply area connectors for backlight and speaker. The locations of the insulating and conducting layers shown in FIG. 7 is representative purposes only, and is not limiting.

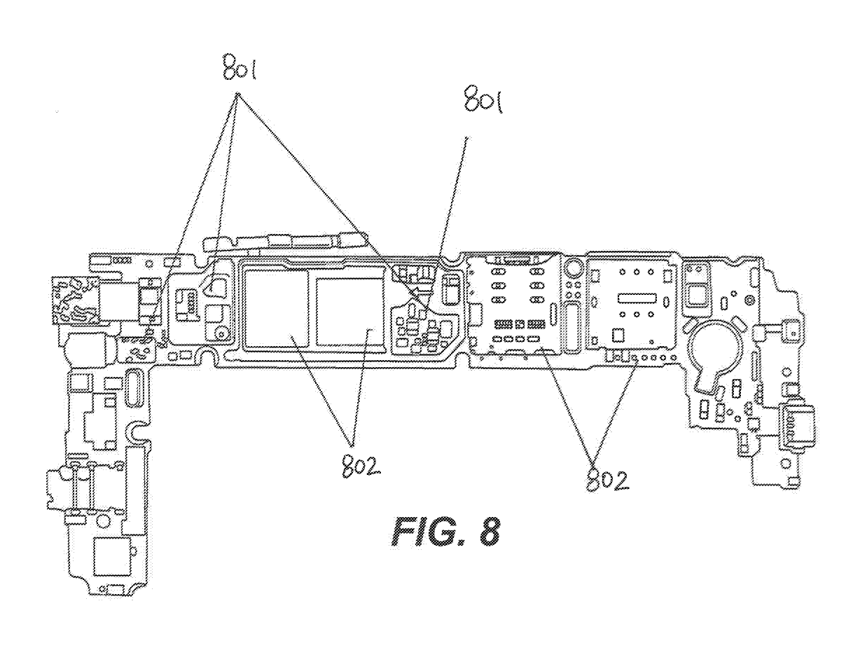

With reference to FIG. 8, which is the front side PCB shown in FIG. 7, there is shown the component locations for the different insulating 801 and conducting 802 coatings according to the present disclosure. It is shown in this figure the coatings specific to the insulating coating around PC connectors for cameras, as well as insulating coatings for components in these areas. This figure also shows polymer coatings for dual SIM card housings, MEMS Mic, USB charging ports, and Headphone jacks, as well as polymer coating for Ram and Rom chips. The locations of the insulating and conducting layers shown in FIG. 8 is representative purposes only, and is not limiting.

Other embodiments of the invention will be apparent to those skilled in the art from consideration of the specification and practice of the invention disclosed herein. It is intended that the specification and examples be considered as exemplary only, with the true scope of the invention being indicated by the following claims.

What is claimed is:

1. A method of protecting an electronic device having a printed circuit board, said method comprising: treating, in any order, the backside and front side of the printed circuit board, wherein said treating the backside of the circuit board comprises:
applying an electrically insulating polymer to the surface of at least component located on the backside of the circuit board;
curing said insulating polymer;
applying a polymer capable of conducting a charge to at least one different component located on the backside of the circuit board than the component with said insulating polymer, wherein said treating the front side of the printed circuit board comprises:
applying an electrically insulating polymer to the surface of at least component located on the front side of the circuit board;
curing the insulating polymer;
applying a polymer capable of conducting a charge to at least one different component located on the front side of the circuit board than the component with said insulating polymer.

2. The method of claim 1, further comprising assembling the electronic device, wherein said assembling comprises:
installing the treated printed circuit board, and a battery in a housing;
connecting the male connectors of the device to base female connectors mounted on the printed circuit board to form a connector; and
applying the insulating polymer to the side of the connector.

3. The method of claim 1, where the insulating polymer is applied to at least one component and/or connector chosen from a PCB connector, an LCD, a battery connector, a speaker connector, a camera connector, a light connector, and combinations thereof.

4. The method of claim 1, where the polymer capable of conducting a charge is applied to at least one component and/or connector chosen from a power switch, a volume switch, RAM Chips, ROM Chips, USB charging port, MEMS, Microphone, SIM card housings, headphone jack, and combinations thereof.

5. The method of claim 1, wherein said first polymer and said second polymer exhibit contact angles ranging from 90° to 120° after curing.

6. The method of claim 1, wherein the first polymer comprises an acrylic-based polymer.

7. The method of claim 6, wherein the acrylic-based polymer is a fluoroacrylate.

8. The method of claim 1, wherein the second polymer comprises a silicone-based polymer.

9. The method of claim 8, wherein the silicone-based polymer is a aliphatic polysiloxane.

10. The method of claim 1, wherein curing the electrically insulating polymer comprises exposing the polymer to ambient conditions for at least 24 hours.

11. The method of claim 1, wherein curing the polymer capable of carrying a charge comprises exposing the polymer to ambient conditions for at least 30 minutes.

12. The method of claim 10, wherein curing the polymer capable of carrying a charge comprises exposing the polymer to a temperature ranging from 90-110° C. for up to 5 minutes.

13. The method of claim 1, wherein applying the insulating polymer and polymer capable of carrying a charge results in a single layer of each polymer on said components.

14. The method of claim 13, wherein the thickness of the single layer of the insulating polymer ranges from 20-1000 nm and the thickness of the single layer of the polymer capable of conducting a charge ranges from 50-500 nm.

15. The method of claim 1, wherein the insulating polymer or the polymer capable of conducting a charge, or both the insulating polymer and polymer capable of conducting a charge are applied by at least one automated or manual deposition technique chosen from dipping, spraying, vacuum deposition, syringe dispensing, and wipe coating.

16. The method of claim 1, wherein when the component has a male end and a female end, the method comprises applying the insulating polymer, or the polymer capable of carrying a charge to both the male end and the female end of the connector prior to connecting the male end to the female end.

17. The method of claim 2, wherein the assembled device has improved hydrophobic properties compared to a device without the coated components.

18. The method of claim 1, wherein the electronic device is selected from a group consisting of a cellular phone, a personal digital assistant (PDA), a tablet, a notebook, a laptop, a desktop computer, a music player, a camera, a video recorder, a battery, an electronic reader, a radio device, a gaming device, a server, headphones, terminal blocks, and control panels, a wearable device, a medical device, a radio controlled device, an industrial device, and an appliance device.

19. An electronic device comprising:
a printed circuit board having a front side and a back side, the backside comprising:
at least one internal connector having an electrically insulating polymer located around the perimeter;
at least one internal component having the insulating polymer located thereon; and;
at least one different internal component having a polymer capable of conducting a charge located thereon, the front side of the printed circuit board comprising:
at least one internal connector having the insulating polymer located around the perimeter;
at least one camera having the insulating polymer located around the perimeter;
at least one internal component having the insulating polymer located thereon; and;
at least one different internal component having a polymer capable of conducting a charge located thereon,

20. The electronic device of claim 19, comprising a housing with an insulating polymer around the perimeter of said housing.

21. The electronic device of claim 19, wherein said insulating polymer and said polymer capable of carrying a charge exhibit contact angles ranging from 90 to 120° after curing.

22. The electronic device of claim 19, wherein the first polymer comprises an acrylic-based polymer.

23. The electronic device of claim 22, wherein the acrylic-based polymer is a fluoroacrylate.

24. The electronic device of claim 19, wherein the second polymer comprises a silicone-based polymer.

25. The electronic device of claim 24, wherein the silicone-based polymer is a aliphatic polysiloxane.

26. The electronic device of claim 19, wherein said one or more component comprises a power switch, a volume switch, a light, a liquid crystal display, a touch-screen, a touch panel, a camera, an antenna, an internal connector, and combinations thereof.

27. The electronic device of claim 19, where the insulating polymer is applied to at least one component and/or connector chosen from an FPC connector, an LCD, a battery connector, a speaker connector, a camera connector, a light connector, and combinations thereof.

28. The electronic device of claim 19, where the polymer capable of conducting a charge is applied to at least one component and/or connector chosen from a power switch, a volume switch, RAM Chips, ROM Chips, USB charging port, MEMS, Microphone, SIM card housings, headphone jack, and combinations thereof.

29. The electronic device of claim 19, wherein said devices comprises a cellular phone, a personal digital assistant (PDA), a tablet, a notebook, a laptop, a desktop computer, a music player, a camera, a video recorder, a battery, an electronic reader, a radio device, a gaming device, a server, headphones, terminal blocks, and control panels, a wearable device, a medical device, a radio controlled device, an industrial device, and an appliance device.

30. The electronic device of claim 19, wherein said device exhibits at least ten (10) times greater water resistance in terms of minutes immersed in water compared to the same device not containing said insulating polymer and the polymer capable of carrying a charge on the printed circuit board.

31. The electronic device of claim 30, wherein said device exhibits at least fifty (50) times greater water resistance in terms of minutes immersed in water compared to the same device not containing said insulating polymer and the polymer capable of carrying a charge on the printed circuit board.

32. The electronic device of claim 19, wherein the thickness of the layer of the insulating polymer ranges from 20-1000 nm and the thickness of the layer of the polymer capable of carrying a charge ranges from 50-500 nm.

33. A smart phone having improved hydrophobic properties comprising:
a printed circuit board having a front side and a back side, the backside comprising:
at least one female connector having an insulating polymer located around the perimeter;
at least one internal component having the insulating polymer located thereon; and;
at least one different internal component having a polymer capable of carrying a charge located thereon,
the front side of the printed circuit board comprising:
at least one female connector having the insulating polymer located around the perimeter;
at least one camera having the insulating polymer located around the perimeter;
at least one internal component having the acrylic-based polymer located thereon; and
at least one different internal component having the polymer capable of carrying a charge located thereon,
the assembled electronic device further comprising the insulating polymer around perimeter of the housing.
